(19) United States
(12) Patent Application Publication
(10) Pub. No.: US 2011/0025909 A1
(43) Pub. Date: Feb. 3, 2011

(54) WAFER-LEVEL CAMERA MODULE AND METHOD FOR COATING THE SAME

(75) Inventor: TAI-SHENG TSAI, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/824,442

(22) Filed: Jun. 28, 2010

(30) Foreign Application Priority Data
Jul. 30, 2009 (CN) 200910304992.6

(51) Int. Cl. H04N 5/225; G03F 7/20

(52) U.S. Cl. 348/374; 430/313; 430/318; 348/E05.024

(57) ABSTRACT

A method for coating wafer level camera modules, comprising: providing a wafer level camera module comprising an outer surface, depositing an opaque layer onto the outer surface, applying a photoresist layer onto the opaque layer, exposing a selected area of the photoresist layer to light to remove the selected area, etching part of the opaque layer within the selected area to form an light incident hole, and removing the remaining photoresist layer.

### BACKGROUND

1. Technical Field

The present disclosure relates to wafer-level camera modules and, more particularly, to a method for coating wafer-level camera modules.

2. Description of Related Art

Miniaturized cameras are widely used in many electronic products, such as mobile phones. Recently, wafer-level camera modules (WLCM) have been used to make such miniaturized cameras. A WLCM defines a light incident hole to allow light to pass through lenses, and it usually needs to be coated. Generally, a piece of adhesive tape/film is affixed to the lens to prevent a selected area of the lens from being coated. After coating, the adhesive tape/film is removed to expose the selected area within the light incident hole. If the adhesive tape/film has been misaligned, some of the coating may be deposited on the selected lens area, which could lead to a low quality camera module and low image quality.

Therefore, what is needed is a method for coating a wafer level camera module to solve the aforementioned problem.

### BRIEF DESCRIPTION OF THE DRAWINGS

The components in the drawings are not necessarily drawn to scale, the emphasis instead being placed upon clearly illustrating the principles of the wafer level camera module coated with a coating method. Moreover, in the drawings, like reference numerals designate corresponding parts throughout the several views.

FIG. 1 is a schematic, cross-sectional view of a wafer-level camera module in accordance with an exemplary embodiment.

FIG. 2 is similar to FIG. 1, but showing that the wafer-level camera module of FIG. 1 is deposited with an opaque layer.

FIG. 3 is similar to FIG. 2, but showing that the wafer-level camera module of FIG. 2 is further deposited with an electromagnetic interference (EMI) shielding layer.

FIG. 4 is similar to FIG. 3, but showing that the wafer-level camera module of FIG. 3 is further deposited with a photoresist layer.

FIG. 5 shows schematically an opaque member to remove part of the photoresist layer.

FIG. 6 is similar to FIG. 4, but showing that part of the photoresist layer has been removed.

FIG. 7 is similar to FIG. 6, but showing that part of the opaque layer and the EMI shielding layer have been removed.

FIG. 8 is similar to FIG. 7, but showing that the remaining photoresist layer has been removed.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

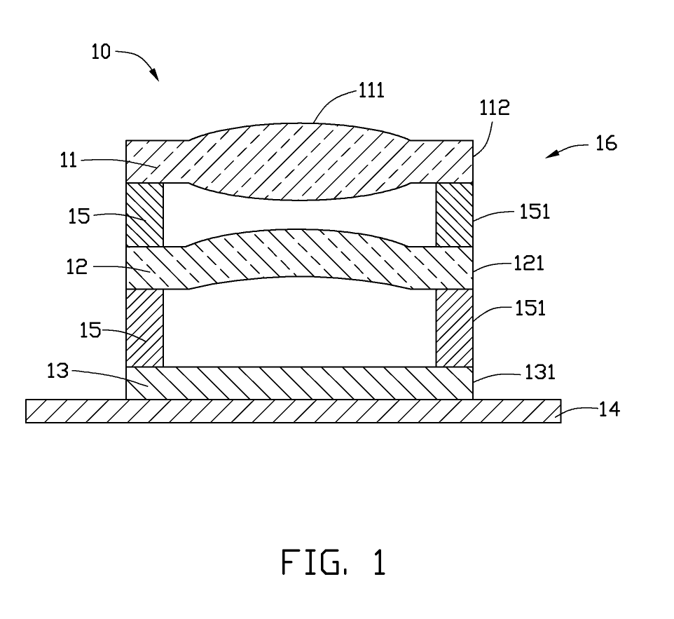

FIGS. 1-8 illustrate a process for forming a coated wafer-level camera module in accordance with an exemplary embodiment. In FIG. 1, a wafer-level camera module (WLCM) 10 is provided. The WLCM 10 includes a first lens 11, a second lens 12, and an image sensor 13 stacked on each other. A plurality of spacers 15 are arranged between the lenses 11 and 12 and between the second lens 12 and the image sensor 13. The image sensor 13 is mounted on a circuit board 14. The WLCM 10 includes an outer surface 16 which includes a top surface 111 of the first lens 11, a side surface 112 of the first lens 11, a side surface 121 of the second lens 12, side surfaces 151 of the spacers 15, and a side surface 131 of the image sensor 13.

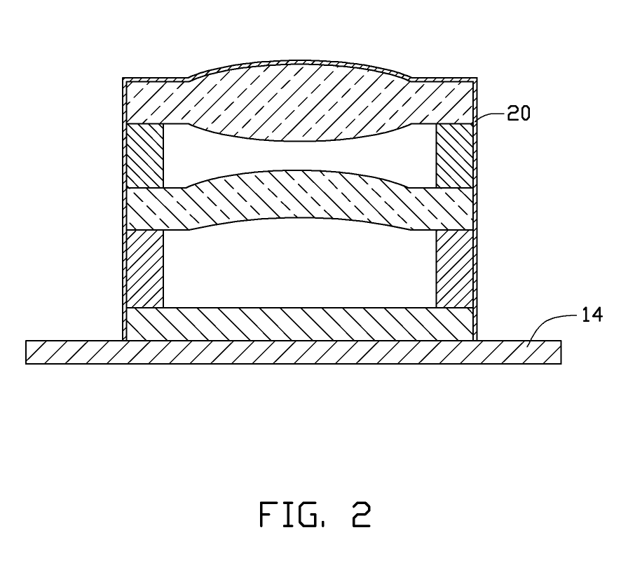

Referring to FIG. 2, the outer surface 16 of the WLCM 10 is deposited with an opaque layer 20. In the exemplary embodiment, the opaque layer 20 includes a black film of chromium nitride. The opaque layer 20 may be made up of other suitable black materials. The opaque layer 20 stays in contact with the circuit board 14.

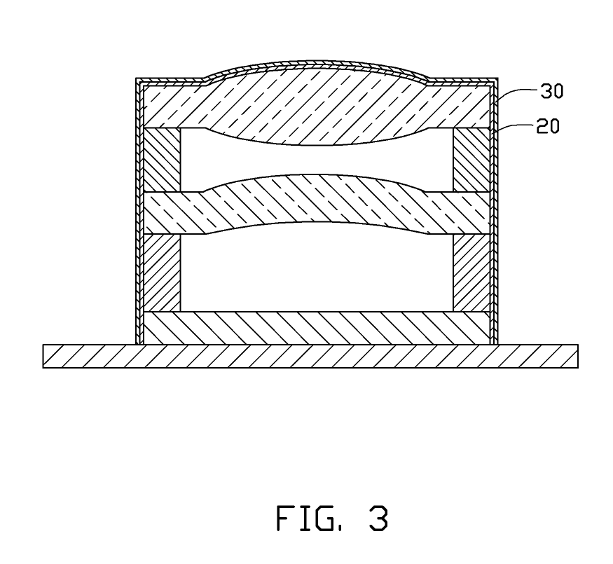

Referring to FIG. 3, an electromagnetic interference (EMI) shielding layer 30 may be deposited onto the opaque layer 20 to prevent EMI. In the embodiment, the opaque layer 20 includes copper and stainless steel. The opaque layer 20 can be formed by sputtering. The electromagnetic shielding layer 30 stays in contact with the circuit board 14 to obtain a better EMI shielding effect.

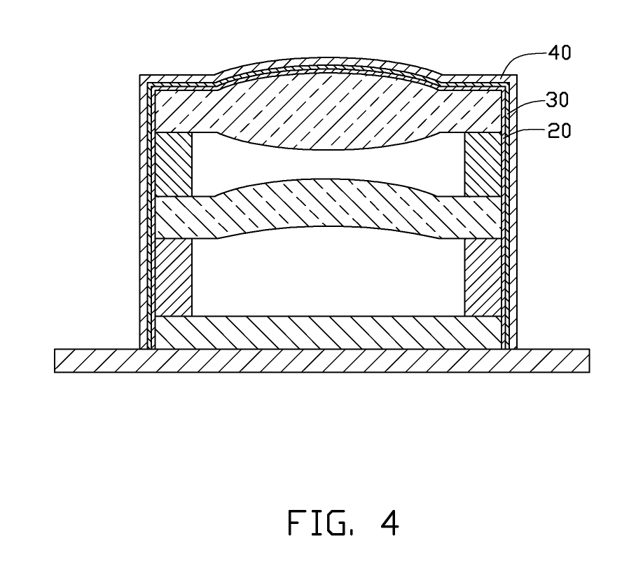

Referring to FIG. 4, a photoresist layer 40 is deposited onto the electromagnetic shielding layer 30. In other embodiments when no electromagnetic shielding layer 30 is deposited onto the opaque layer 20, the photoresist layer 40 is deposited onto the opaque layer 20. In the embodiment, the photoresist layer 40 is a positive resist, that is, the portion of the photoresist layer 40 that is exposed to light becomes soluble.

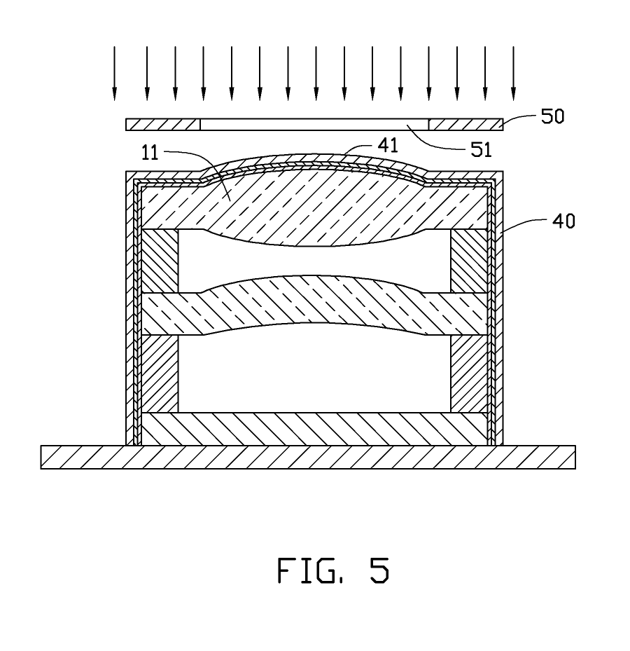

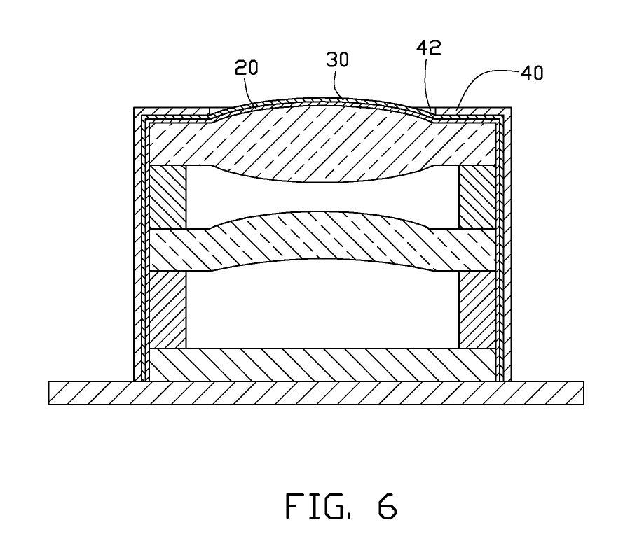

Referring to FIGS. 5-6, an opaque member 50 is provided. The opaque member 50 is round plate that has substantially the same size as the first lens 11. The opaque member 50 defines a through hole 51. The opaque member 50 is arranged above and aligned with the first lens 11, to cause the through hole 51 to stay in position with a selected portion 41 of the photoresist layer 40. Upon being exposed through the through hole 51 to a light source (not shown), the selected portion 41 becomes soluble and can thus be removed, which forms an opening 42.

In another embodiment, the photoresist layer 40 may be a negative resist. The opaque member 50 is shaped to have substantially the same size as the selected portion 41 of the photoresist layer 40. The opaque member 50 is arranged above the first lens 11 and is aligned with the selected portion 41. The selected portion 41 is thus prevented from being exposed by the opaque member 50 and thus becomes soluble and can thus be removed.

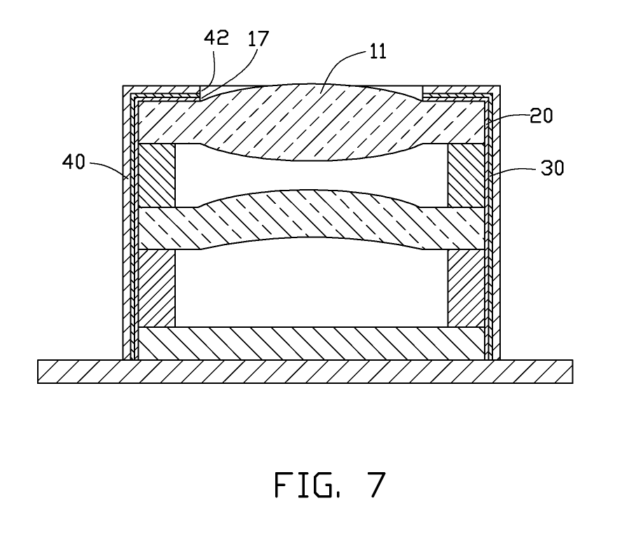

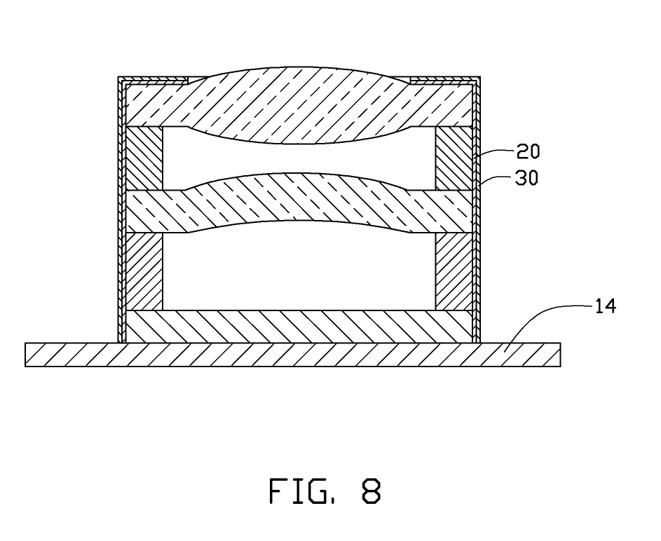

Referring to FIG. 7, after the selected portion 41 is removed, part of the opaque layer 20 and the electromagnetic shielding layer 30 within the opening 42 of the photoresist layer 40 are etched, removing part of the opaque layer 20. The electromagnetic shielding layer 30 thus forms a light incident hole 17 to allow light to pass through the first lens 11. In the embodiment, the opaque layer 20 and the electromagnetic shielding layer 30 are etched by anisotropically plasma etching with carbon tetrafluoride and oxygen. The etching direction is along axes of the lenses 11 and 12. After the light incident hole 17 is formed, the remaining photoresist layer 40 is removed as described above (shown in FIG. 8).

The opaque member 50 can be precisely made and aligned with the lens 11, which ensures the light incident hole 17 is aligned with the lens 11 with high precision and further ensures the image quality capturing by the camera module 10.

While various embodiments have been described and illustrated, the disclosure is not to be constructed as being limited thereto. Various modifications can be made to the embodiments by those skilled in the art without departing from the true spirit and scope of the disclosure as defined by the appended claims.

What is claimed is:

1. A method for coating wafer level camera modules, comprising:
providing a wafer level camera module comprising an outer surface;
depositing an opaque layer onto the outer surface;
applying a photoresist layer onto the opaque layer;
exposing the photoresist layer to light to remove a selected portion of the photoresist layer;
etching part of the opaque layer corresponding to the selected portion to form an light incident hole; and
removing the photoresist layer.

2. The method for coating wafer level camera modules according to claim 1 further comprising: depositing an electromagnetic shielding layer onto the opaque layer, wherein the photoresist layer is coated onto the electromagnetic shielding layer, the etching also removes part of the electromagnetic shielding layer.

3. The method for coating wafer level camera modules according to claim 1, wherein the photoresist layer is a positive resist and the exposing step comprises: providing an opaque member defining a through hole having the same size as the light incident hole, arranging the opaque member above the photoresist layer and aligning the through hole with the selected portion, and exposing the selected portion via the through hole to remove the selected portion.

4. The method for coating wafer level camera modules according to claim 1, wherein the photoresist layer is negative resist and the exposing step comprises: providing an opaque member having the same size as the light incident hole, arranging the opaque member above the photoresist layer and aligning the opaque member with the selected area, and exposing the selected area.

5. The method for coating wafer level camera modules according to claim 1, wherein the opaque layer comprises black film of chromium nitride.

6. The method for coating wafer level camera modules according to claim 2, wherein the electromagnetic shielding layer comprises copper and stainless steel.

7. The method for coating wafer level camera modules according to claim 2, wherein the electromagnetic shielding layer is formed by sputtering.

8. The method for coating wafer level camera modules according to claim 2, wherein the etching is anisotropically plasma etching with carbon tetrafluoride and oxygen.

9. A wafer level camera module comprising:
an image sensor;
a wafer level lens module comprising a lens; and
an outer surface deposited with an opaque layer defining a light incident hole to allow light to pass through the lens to be received by the image sensor.

10. The wafer level camera module according to claim 9 further comprising a circuit board and an electromagnetic shielding layer deposited onto the opaque layer, wherein the electromagnetic shielding layer stays in contact with the circuit board.

11. The wafer level camera module according to claim 10, wherein the opaque layer stays in contact with the circuit board.
